(19) United States
(12) Patent Application Publication
(10) Pub. No.: US 2024/0426675 A1
(43) Pub. Date: Dec. 26, 2024

(54) METHOD AND CIRCUIT ARRANGEMENTS FOR DETERMINING A BARRIER-LAYER TEMPERATURE OF A SEMICONDUCTOR COMPONENT HAVING AN INSULATED GATE

(71) Applicant: Robert Bosch GmbH, Stuttgart (DE)

(72) Inventors: Manuel Riefer, Reutlingen (DE); Jonathan Winlker, Sonnenbuehl (DE)

(21) Appl. No.: 18/682,407

(22) PCT Filed: Sep. 19, 2022
(86) PCT No.: PCT/EP2022/075893

§ 371 Date: Feb. 8, 2024

(30) Foreign Application Priority Data
Sep. 27, 2021 (DE) 10 2021 210 733.8

(51) Int. Cl. G01K 7/01; G01K 7/42; G01R 31/26

(52) U.S. Cl. CPC G01K 7/015; G01K 7/42; G01R 31/2619; G01R 31/2628; G01K 2217/00

(57) ABSTRACT

Methods and circuit arrangement for ascertaining a barrier-layer temperature of a semiconductor component having an insulated gate. A method for ascertaining the barrier-layer temperature of the semiconductor component has the following steps: controlling a gate of the semiconductor component having an insulated gate by means of a predefined inrush current at a first switch-on phase time through a current-controlled gate driver in order to begin a switching-on process of the semiconductor component; starting a switch-on phase time measurement at the first switch-on phase time; ascertaining a second switch-on phase time, which represents a threshold voltage of the semiconductor component being reached, by detecting a rising current edge in a load path of the semiconductor component; and ascertaining a current barrier-layer temperature of the semiconductor component on the basis of a time difference between the second switch-on phase time and the first switch-on phase time.

### FIELD

The present invention relates to methods and circuit arrangements for ascertaining a barrier-layer temperature of a semiconductor component having an insulated gate.

### BACKGROUND INFORMATION

Voltage-controlled gate drivers for semiconductor components are available in the related art, which are used, for example, in power devices, such as inverters, etc.

Furthermore, semiconductor components having a wide band gap are available in the related art, which, due to advantageous electrical and thermal properties (e.g., significantly faster switching speeds), are becoming increasingly widespread in the field of power electronics. In connection with such semiconductor components, it should be noted that such faster switching speeds can cause undesired side effects, such as unintentional parasitic switching on and/or high generated voltages due to commutation inductances, etc.

In order to avoid such undesired side effects, switching processes of such semiconductor components are carried out, for example, by means of a current-controlled gate driver which is capable of generating current values adapted to the respective switching phases of the semiconductor components for controlling the semiconductor components.

In addition, methods and devices for determining temperatures of such semiconductor components on the basis of temperature-dependent resistances and/or temperature-sensitive parameters are conventional.

### SUMMARY

According to a first aspect of the present invention, a method for ascertaining a barrier-layer temperature of a semiconductor component having an insulated gate is provided, wherein the method is used during a switching-on process of the semiconductor component. The semiconductor component is, for example, an Si-MOSFET, an SiC-MOSFET, an IGBT or a semiconductor component that differs therefrom and has an insulated gate. The semiconductor component is used, for example, in a power device, such as an inverter or a device that differs therefrom.

In a first step of the method according to an example embodiment of the present invention, a gate of the semiconductor component is controlled by means of a predefined inrush current at a first switch-on phase time through a current-controlled gate driver in order to begin a switching-on process of the semiconductor component.

In a second step of the method according to an example embodiment of the present invention, a switch-on phase time measurement is started at the first switch-on phase time. The time measurement is carried out, for example, by means of an evaluation unit according to the present invention, which is, for example, a component of the gate driver itself or an independent component. The connecting of such an evaluation unit to the gate driver by means of information technology thus allows the start of the switching-on process to be transmitted to the evaluation unit or alternatively allows the start of the switching-on process to be initiated by the evaluation unit.

In a third step of the method according to an example embodiment of the present invention, a second switch-on phase time, which represents a threshold voltage of the semiconductor component being reached, is ascertained by detecting a rising current edge in a load path of the semiconductor component. The threshold voltage of the semiconductor component being reached corresponds to a transition between a precharge phase of an input capacitance of the semiconductor component and a start of a current commutation phase (di/dt phase) of the semiconductor component. The second switch-on phase time is ascertained, for example, by means of a detection circuit (described later), which can be connected to the evaluation unit by means of information technology, so that the evaluation unit is able to register the second switch-on phase time on the basis of the detection circuit.

In a fourth step of the method according to an example embodiment of the present invention, a current barrier-layer temperature of the semiconductor component is ascertained on the basis of a time difference between the second switch-on phase time and the first switch-on phase time. For this purpose, it is possible that the evaluation unit stores the first switch-on phase time and the second switch-on phase time in a memory unit connected to the evaluation unit in order to then ascertain the time difference on the basis of the stored values.

The method according to an example embodiment of the present invention makes use of the fact that a duration of the precharge phase is dependent on the current barrier-layer temperature of the semiconductor component. Based on a predefined association between a relevant duration of the precharge phase and respective associated barrier-layer temperature values, which are stored, for example, in a lookup table that can be called up by the evaluation unit, it is accordingly possible to ascertain respective barrier-layer temperatures with high sensitivity at runtime. In this way, precise measurement values with regard to a current load of the semiconductor component are obtained with a particularly low reaction time.

A calibration of the time-temperature relationships of the semiconductor component takes place preferably before the first use and/or at times which follow the first use, in order to ensure a required accuracy of a barrier-layer temperature determination according to an example embodiment of the present invention.

According to a second aspect of the present invention, a method for ascertaining a barrier-layer temperature of a semiconductor component having an insulated gate is proposed, wherein the method is used during a switching-off process of the semiconductor component. The semiconductor component is, for example, as described above, an Si-MOSFET, an SiC-MOSFET, an IGBT or a semiconductor component that differs therefrom and has an insulated gate. The semiconductor component is also used, for example, in a power device, such as an inverter or a device differing therefrom.

In a first step of the method according to an example embodiment of the present invention, a gate of the semiconductor component is controlled by means of a predefined switch-off current at a first switch-off phase time through a current-controlled gate driver in order to begin a switching-off process of the semiconductor component.

In a second step of the method according to an example embodiment of the present invention, a switch-off phase time measurement is started at the first switch-off phase time. The time measurement is carried out, for example, by means of an evaluation unit according to the present invention, which is, for example, a component of the gate driver or an independent component. The connecting of such an evaluation unit to the gate driver by means of information technology thus allows the start of the switching-off process to be transmitted to the evaluation unit or alternatively allows the start of the switching-off process to be initiated by the evaluation unit.

In a third step of the method according to an example embodiment of the present invention, a second switch-off phase time, which represents a plateau voltage of the semiconductor component being reached, is ascertained by detecting a falling voltage edge in a load path of the semiconductor component. The plateau voltage of the semiconductor component being reached corresponds to a transition between a predischarge phase of an input capacitance of the semiconductor component and a start of a voltage commutation phase (du/dt phase) of the semiconductor component. The second switch-off phase time is ascertained, for example, by means of a detection circuit (described later), which is connected to the evaluation unit by means of information technology, so that the evaluation unit is able to register the second switch-off phase time on the basis of the detection circuit.

In a fourth step of the method according to an example embodiment of the present invention, a current barrier-layer temperature of the semiconductor component is ascertained on the basis of a time difference between the second switch-off phase time and the first switch-off phase time and on the basis of a current load current of the semiconductor component.

The advantages resulting therefrom and the implementation possibilities of the method according to the present invention in connection therewith apply analogously as described in connection with the above-described ascertainment of the barrier-layer temperature during the switching-on process, which is why reference is made in this respect to the above statements in order to avoid repetitions.

Preferred developments of the present invention are disclosed herein.

Advantageously, according to an example embodiment of the present invention, a current profile is ascertained as a function of the ascertained barrier-layer temperature and is used by the current-controlled gate driver during the current switching process (i.e., during a switching-on process and/or a switching-off process) and/or during a subsequent switching process for controlling the gate of the semiconductor component. Such a current profile preferably defines time sequences of respective current values to be used by the current-controlled gate driver. This has the advantage that respective switchover times, defined by the current profile of gate currents and/or heights of the respective gate currents can always be optimally adapted to the current barrier-layer temperature of the semiconductor component. It should be noted that independent current profiles can be predefined and used for switching-on and switching-off processes. In addition, it is possible to select the current profile to be ascertained as a function of the barrier-layer temperature from a plurality of predefined current profiles, which are present, for example, in the form of one or more characteristic maps (e.g., in a memory unit). Alternatively or additionally, it is also possible to dynamically ascertain the current profile to be ascertained as a function of the barrier-layer temperature at runtime.

The predefined inrush current and/or the predefined switch-off current is preferably defined as a function of a required accuracy of the time measurement. In other words, it can be useful or necessary, as a function of a used time measurement method, a maximum possible time resolution associated therewith, a detection accuracy of start and end times of the time measurement, etc., to select the inrush current and/or the switch-off current to be lower than in a case in which no barrier-layer temperature measurement is carried out on the basis of the method according to the present invention.

In an advantageous embodiment of the present invention, the barrier-layer temperature of the semiconductor component is ascertained only during predefined operating phases of the semiconductor component (e.g., at high load currents, which can lead to high heating of the semiconductor component) and/or during each switching-on process and/or each switching-off process of the semiconductor component and/or alternately with at least one further semiconductor component.

Particularly advantageously, according to an example embodiment of the present invention, a barrier-layer temperature of the semiconductor component is realized both during a switching-on process as described above, and during a switching-off process of the semiconductor component as described above, so that, for example in both switching processes, current profiles adapted to the relevant barrier-layer temperature can be used optimally in each case.

According to a third aspect of the present invention, a circuit arrangement for ascertaining a barrier-layer temperature of a semiconductor component having an insulated gate is provided. According to an example embodiment of the present invention, the circuit arrangement includes: a semiconductor component having an insulated gate, a current-controlled gate driver, a first detection circuit, and a first evaluation unit. The gate driver is, for example, a gate driver integrated into an ASIC or a gate driver designed to differ therefrom. The first evaluation unit is designed, for example, as an ASIC, FPGA, processor, digital signal processor, microcontroller, analog circuit or the like, and can be a component of the gate driver itself or an independent component. The current-controlled gate driver is configured to control a gate of the semiconductor component by means of a predefined inrush current at a first switch-on phase time in order to begin a switching-on process of the semiconductor component. The first evaluation unit is configured to start a switch-on phase time measurement at the first switch-on phase time. The first detection circuit is configured to detect a threshold voltage of the semiconductor component being reached by detecting a rising current edge in a load path of the semiconductor component and to output a first signaling to the first evaluation unit in response to the threshold voltage being reached. The current edge is ascertained, for example, on the basis of a parasitic inductance of a connection line of a semiconductor module which contains the semiconductor component, without thereby making a limitation to this type of ascertainment of the current edge. The first evaluation unit is further configured to register a second switch-on phase time in response to the received first signaling of the first detection circuit and to ascertain a current barrier-layer temperature of the semiconductor component on the basis of a time difference between the second switch-on phase time and the first switch-on phase time. The features, combinations of features and the advantages resulting therefrom correspond to those discussed in connection with the first-mentioned aspect of the present invention, such that reference is made to the above statements in order to avoid repetitions.

According to a fourth aspect of the present invention, a circuit arrangement for ascertaining a barrier-layer temperature of a semiconductor component having an insulated gate is provided. According to an example embodiment of the present invention, the circuit arrangement includes: a semiconductor component having an insulated gate, a current-controlled gate driver, a second detection circuit, and a second evaluation unit. The gate driver is, for example, a gate driver integrated into an ASIC or a gate driver designed to differ therefrom. The second evaluation unit is designed, for example, as an ASIC, FPGA, processor, digital signal processor, microcontroller, analog circuit or the like, and can be a component of the gate driver itself or an independent component. The current-controlled gate driver is configured to control a gate of the semiconductor component by means of a predefined switch-off current at a first switch-off phase time in order to begin a switching-off process of the semiconductor component. The second evaluation unit is configured to start a switch-off phase time measurement at the first switch-off phase time. The second detection circuit is configured to detect a plateau voltage of the semiconductor component being reached by detecting a falling voltage edge in a load path of the semiconductor component and, in response to the plateau voltage being reached, to output a second signaling to the second evaluation unit. The second evaluation unit is further configured to register a second switch-off phase time in response to the received second signaling of the second detection circuit and to ascertain a current barrier-layer temperature of the semiconductor component on the basis of a time difference between the second switch-off phase time and the first switch-off phase time and on the basis of a current load current.

Particularly advantageously, the circuit arrangement for ascertaining a barrier-layer temperature of a semiconductor component having an insulated gate has a circuit arrangement as described above for ascertaining a barrier-layer temperature during a switching-on process of the semiconductor component and a circuit arrangement as described above for ascertaining a barrier-layer temperature during a switching-off process of the semiconductor component. In such a case, the first evaluation unit and the second evaluation unit are preferably one and the same evaluation unit, without being limited thereto.

In a further advantageous embodiment of the present invention, the semiconductor component is a first semiconductor component. In addition, the circuit arrangement has at least one second semiconductor component which is arranged such that it forms a common topological (or logical) switch with the first semiconductor component in a series circuit or in a parallel circuit. In addition, it is possible for further semiconductor components in a series circuit and/or parallel circuit to be arranged relative to the first semiconductor component and to the second semiconductor component and to form a single topological switch overall. The circuit arrangement is also configured to derive a barrier-layer temperature of the second semiconductor component from the ascertained barrier-layer temperature of the first semiconductor component or to ascertain a barrier-layer temperature of the second semiconductor component separately in a corresponding manner to ascertain the barrier-layer temperature of the first semiconductor component. This applies analogously also to further semiconductor components of the topological switch, which are optionally connected in parallel and/or in series.

### BRIEF DESCRIPTION OF THE DRAWINGS

Exemplary embodiments of the present invention are described in detail below with reference to the figures.

FIG. 1 shows an exemplary gate current profile and a corresponding gate voltage curve for illustrating a method according to the present invention for ascertaining a barrier-layer temperature of a semiconductor component having an insulated gate.

FIG. 2 shows an embodiment of a circuit arrangement according to the present invention for ascertaining a barrier-layer temperature of a semiconductor component having an insulated gate during a switching-on process.

FIG. 3 shows an embodiment of a circuit arrangement according to the present invention for ascertaining a barrier-layer temperature of a semiconductor component having an insulated gate during a switching-off process.

### DETAILED DESCRIPTION OF EXAMPLE EMBODIMENTS

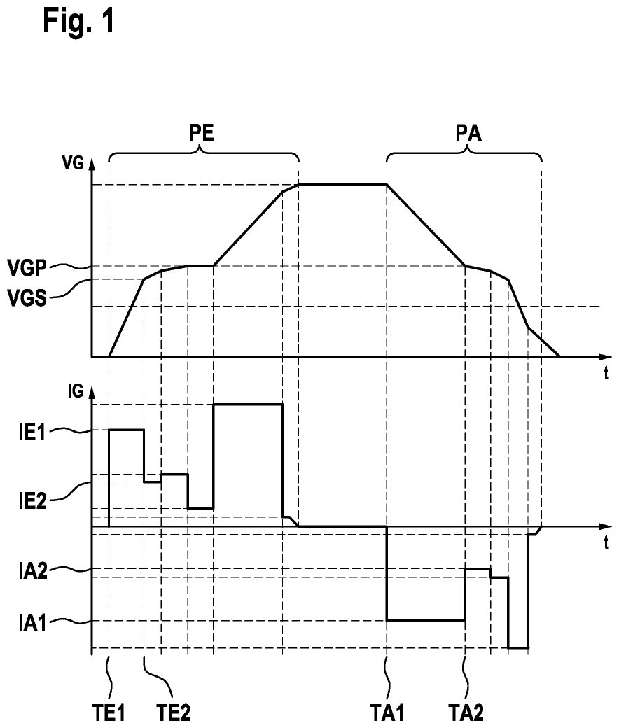

FIG. 1 shows an exemplary gate current profile (the upper diagram showing IG over t) and a corresponding gate voltage curve (the lower diagram showing VG over t) for illustrating a method according to the present invention for ascertaining a barrier-layer temperature of a semiconductor component designed here as an SiC-MOSFET 10, which is referred to below in a shortened form as MOSFET 10.

The gate current profile is stored, for example, in a memory unit of an ASIC, which functions here as a current-controlled gate driver 20 for controlling the MOSFET 10.

The MOSFET 10 is initially in a switched-off state and is controlled at the beginning of a switching-on process PE to be carried out at a first switch-on phase time TE1 through the gate driver 20 with a first inrush current IE1 in order to begin the switching-on process PE of the semiconductor component.

In addition, a switch-on phase time measurement is started at the first switch-on phase time TE1.

A second switch-on phase time TE2, which represents a threshold voltage VGS of the semiconductor component 10 being reached, is then ascertained by detecting a rising current edge in a load path of the semiconductor component 10. From the second switch-on time TE2, the switching-on process is continued in accordance with a predefined inrush current profile with a second inrush current IE2, which is further adapted in subsequent switch-on phases (not described in more detail).

Furthermore, a current barrier-layer temperature of the semiconductor component 10 is ascertained on the basis of a time difference between the second switch-on phase time TE2 and the first switch-on phase time TE1.

As a function of a height of the barrier-layer temperature ascertained in this way, a predefined switch-off current profile is selected from a plurality of predefined switch-off current profiles.

After completion of the switching-on process PE, the MOSFET 10 is in a switched-on state. In a subsequent switch-off phase PA, the barrier-layer temperature of the MOSFET 10 is subsequently ascertained again. For this purpose, the switch-off current profile ascertained during the switch-on phase PE is used to control the gate of the MOSFET 10 through the gate driver at the beginning of the switch-off phase PA in accordance with the switch-off current profile by means of a first switch-off phase current IA1. The start of the switch-off phase PA corresponds to a first switch-off phase time TA1.

In addition, a switch-off phase time measurement is started at the first switch-off phase time TA1.

A second switch-off phase time TA2, which represents a plateau voltage VGP of the semiconductor component 10 being reached, is then ascertained by detecting a falling voltage edge in the load path of the semiconductor component 10. From the second switch-off time TA2, the switching-off process is continued in accordance with the switch-off current profile with a second switch-off current IA2, which is further adapted in subsequent switch-off phases (not described in more detail).

Furthermore, a current barrier-layer temperature of the semiconductor component 10 is ascertained on the basis of a time difference between the second switch-off phase time TA2 and the first switch-off phase time TA1.

As a function of a height of the barrier-layer temperature ascertained in this way, a predefined inrush current profile is selected from a plurality of predefined inrush current profiles for a subsequent switching-on process.

It should be noted that a height of the first inrush current IE1 and a height of the first switch-off current IA1 are each defined lower than a reliable switching-on process or switching-off process would allow in order to increase an accuracy of a relevant time measurement between the switch-on phase times TE1, TE2 and between the switch-off phase times TAI, TA2 in order thereby to be able to determine the respective barrier-layer temperatures of the MOSFET 10 more precisely.

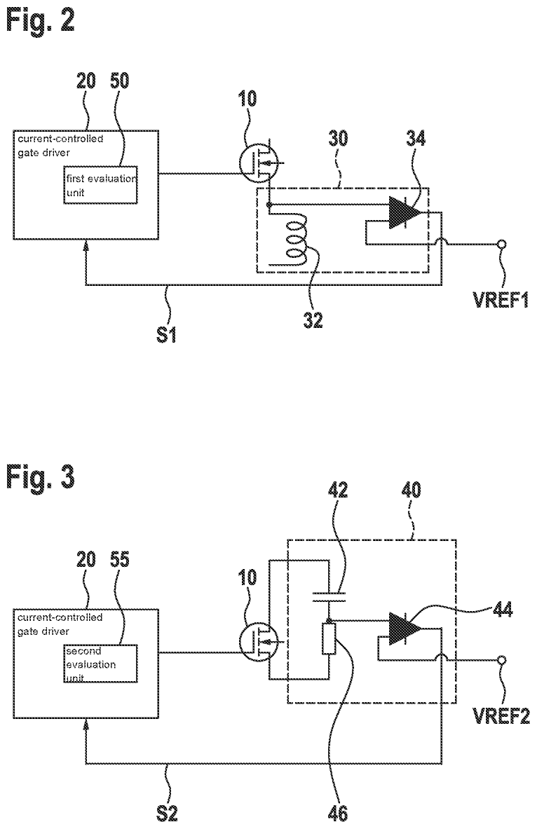

FIG. 2 shows a circuit arrangement according to the present invention for ascertaining a barrier-layer temperature of a semiconductor component designed as an SiC-MOSFET 10 (hereinafter referred to in a shortened form as a MOSFET) during a switching-on process of the MOSFET 10. The circuit arrangement has a gate driver 20 having a first evaluation unit 50, a MOSFET 10 and a first detection circuit 30, which are composed of a parasitic inductance 32 of a connection line of a semiconductor module containing the MOSFET 10, and a first comparator 34.

As soon as a current flow in the load path of the MOSFET 10 begins during a switching-on process PE of the MOSFET 10, a voltage drops across the inductance 32, which voltage is compared by the first comparator 34 with a first reference voltage VREF1. As soon as the first reference voltage VREF 1 has been reached, the first comparator 34 outputs a first signal S1 to the first evaluation unit 50 of the gate driver 20 which, on the basis of the first signal S1, terminates a time measurement started at the beginning of the switching-on process and ascertains a barrier-layer temperature of the MOSFET 10 on the basis of this time measurement.

It should be noted that embodiments of the first detection circuit differing therefrom can also be used.

FIG. 3 shows a circuit arrangement according to the present invention for ascertaining a barrier-layer temperature of a semiconductor component designed as an SiC-MOSFET 10 (hereinafter referred to in a shortened form as a MOSFET) during a switching-off process of the MOSFET 10. The circuit arrangement has a gate driver 20 having a second evaluation unit 55, a MOSFET 10 and a second detection circuit 40, which is composed of a second comparator 44 and a voltage divider composed of a capacitor 42 and a resistor 46.

As soon as a voltage across the resistor 46 drops in a switching-off process PA of the MOSFET 10, which voltage is greater than a second reference voltage VREF2, a second signal S2 is output by the second comparator 44, which compares these two voltages, to the second evaluation unit 55 of the gate driver 20, which then terminates a time measurement started at the beginning of the switching-off process on the basis of the second signal S2 and ascertains a barrier-layer temperature of the MOSFET 10 on the basis of this time measurement.

It should be noted that embodiments of the second detection circuit differing therefrom can also be used.

It should additionally be noted that the circuit arrangement described in FIG. 2 and the circuit arrangement described in FIG. 3 can be designed as a common circuit arrangement which is accordingly able to realize a barrier-layer temperature both in a switching-on process PE and in a switching-off process PA of the MOSFET 10. In such a case, the first evaluation unit 50 and the second evaluation unit 55 described here are preferably designed as one and the same evaluation unit.

1-10. (canceled)

11. A method for ascertaining a barrier-layer temperature of a semiconductor component having an insulated gate, comprising the following steps:
controlling a gate of the semiconductor component having the insulated gate using a predefined inrush current at a first switch-on phase time through a current-controlled gate driver to begin a switching-on process of the semiconductor component;
starting a switch-on phase time measurement at the first switch-on phase time;
ascertaining a second switch-on phase time, which represents a threshold voltage of the semiconductor component being reached, by detecting a rising current edge in a load path of the semiconductor component; and
ascertaining a current barrier-layer temperature of the semiconductor component based on a time difference between the second switch-on phase time and the first switch-on phase time.

12. A method for ascertaining a barrier-layer temperature of a semiconductor component having an insulated gate, comprising the following steps:
controlling a gate of the semiconductor component having the insulated gate using a predefined switch-off current at a first switch-off phase time through a current-controlled gate driver to begin a switching-off process of the semiconductor component;
starting a switch-off phase time measurement at the first switch-off phase time;
ascertaining a second switch-off phase time, which represents a plateau voltage of the semiconductor component being reached, by detecting a falling voltage edge in a load path of the semiconductor component; and
ascertaining a current barrier-layer temperature of the semiconductor component based on a time difference between the second switch-off phase time and the first switch-off phase time and based on a current load current of the semiconductor component.

13. The method according to claim 11, wherein, as a function of the ascertained barrier-layer temperature, a current profile is ascertained which is used by the current-controlled gate driver during a current switching process and/or during a subsequent switching process for controlling the gate of the semiconductor component.

14. The method according to claim 12, wherein, as a function of the ascertained barrier-layer temperature, a current profile is ascertained which is used by the current-controlled gate driver during a current switching process and/or during a subsequent switching process for controlling the gate of the semiconductor component.

15. The method according to claim 11, wherein the predefined inrush current is defined as a function of a required accuracy of the time measurement.

16. The method according to claim 12, wherein the predefined switch-off current is defined as a function of a required accuracy of the time measurement.

17. The method according to claim 11, wherein the barrier-layer temperature of the semiconductor component is ascertained:
only during predefined operating phases of the semiconductor component, and/or
during each switching-on process of the semiconductor component, and/or
alternating with at least one further semiconductor component.

18. The method according to claim 12, wherein the barrier-layer temperature of the semiconductor component is ascertained:
only during predefined operating phases of the semiconductor component, and/or
during each switching-off process of the semiconductor component, and/or
alternating with at least one further semiconductor component.

19. A method for ascertaining a barrier-layer temperature of a semiconductor component having an insulated gate, comprising the following steps:
carrying out a switching-on process of the semiconductor component including:
controlling a gate of the semiconductor component having the insulated gate using a predefined switch-off current at a first switch-off phase time through a current-controlled gate driver to begin a switching-off process of the semiconductor component,
starting a switch-off phase time measurement at the first switch-off phase time,
ascertaining a second switch-off phase time, which represents a plateau voltage of the semiconductor component being reached, by detecting a falling voltage edge in a load path of the semiconductor component, and
ascertaining a current barrier-layer temperature of the semiconductor component based on a time difference between the second switch-off phase time and the first switch-off phase time and based on a current load current of the semiconductor component; and
carrying out a switching-off process of the semiconductor component including:
controlling the gate of the semiconductor component having the insulated gate using a predefined switch-off current at a first switch-off phase time through a current-controlled gate driver to begin a switching-off process of the semiconductor component,
starting a switch-off phase time measurement at the first switch-off phase time,
ascertaining a second switch-off phase time, which represents a plateau voltage of the semiconductor component being reached, by detecting a falling voltage edge in a load path of the semiconductor component, and
ascertaining the current barrier-layer temperature of the semiconductor component based on a time difference between the second switch-off phase time and the first switch-off phase time and based on a current load current of the semiconductor component.

20. A circuit arrangement for ascertaining a barrier-layer temperature of a semiconductor component having an insulated gate, comprising:
a semiconductor component having an insulated gate;
a current-controlled gate driver;
a first detection circuit; and
a first evaluation unit;
wherein:
the current-controlled gate driver is configured to control a gate of the semiconductor component using a predefined inrush current at a first switch-on phase time to begin a switching-on process of the semiconductor component,
the first evaluation unit is configured to start a switch-on phase time measurement at the first switch-on phase time,
the first detection circuit is configured to detect a threshold voltage of the semiconductor component being reached by detecting a rising current edge in a load path of the semiconductor component and to output a first signaling to the first evaluation unit in response to the threshold voltage being reached, and
the first evaluation unit is configured to:
register a second switch-on phase time in response to the received first signaling of the first detection circuit, and
ascertain a current barrier-layer temperature of the semiconductor component based on a time difference between the second switch-on phase time and the first switch-on phase time.

21. A circuit arrangement for ascertaining a barrier-layer temperature of a semiconductor component having an insulated gate, comprising:
a semiconductor component having an insulated gate;
a current-controlled gate driver;
a second detection circuit; and
a second evaluation unit;
wherein
the current-controlled gate driver is configured to control a gate of the semiconductor component using a predefined switch-off current at a first switch-off phase time to begin a switching-off process of the semiconductor component,
the second evaluation unit is configured to start a switch-off phase time measurement at the first switch-off phase time,
the second detection circuit is configured to detect a plateau voltage of the semiconductor component being reached by detecting a falling voltage edge in a load path of the semiconductor component and, in response to the plateau voltage being reached, to output a second signaling to the second evaluation unit, and
the second evaluation unit is configured to:
register a second switch-off phase time in response to the received second signaling of the second detection circuit, and
ascertain a current barrier-layer temperature of the semiconductor component based on a time difference between the second switch-off phase time and the first switch-off phase time.

22. The circuit arrangement according to claim 20, further comprising:
a second detection circuit; and
a second evaluation unit;
wherein
the current-controlled gate driver is configured to control a gate of the semiconductor component using a predefined switch-off current at a first switch-off phase time to begin a switching-off process of the semiconductor component,
the second evaluation unit is configured to start a switch-off phase time measurement at the first switch-off phase time,
the second detection circuit is configured to detect a plateau voltage of the semiconductor component being reached by detecting a falling voltage edge in a load path of the semiconductor component and, in response to the plateau voltage being reached, to output a second signaling to the second evaluation unit, and
the second evaluation unit is configured to:
register a second switch-off phase time in response to the received second signaling of the second detection circuit, and
ascertain the current barrier-layer temperature of the semiconductor component based on a time difference between the second switch-off phase time and the first switch-off phase time.

23. The circuit arrangement according to claim 20, wherein
the semiconductor component is a first semiconductor component,
the circuit arrangement has at least one second semiconductor component, and
the circuit arrangement is configured to:
derive a barrier-layer temperature of the second semiconductor component from the ascertained barrier-layer temperature of the first semiconductor component, or
ascertain a barrier-layer temperature of the second semiconductor component in a corresponding manner for ascertaining the barrier-layer temperature of the first semiconductor component.

24. The circuit arrangement according to claim 21, wherein
the semiconductor component is a first semiconductor component,
the circuit arrangement has at least one second semiconductor component, and
the circuit arrangement is configured to:
derive a barrier-layer temperature of the second semiconductor component from the ascertained barrier-layer temperature of the first semiconductor component, or
ascertain a barrier-layer temperature of the second semiconductor component in a corresponding manner for ascertaining the barrier-layer temperature of the first semiconductor component.

25. The circuit arrangement according to claim 22, wherein
the semiconductor component is a first semiconductor component,
the circuit arrangement has at least one second semiconductor component, and
the circuit arrangement is configured to:
derive a barrier-layer temperature of the second semiconductor component from the ascertained barrier-layer temperature of the first semiconductor component, or
ascertain a barrier-layer temperature of the second semiconductor component in a corresponding manner for ascertaining the barrier-layer temperature of the first semiconductor component.
